(19) United States
(12) Patent Application Publication
(10) Pub. No.: US 2015/0180441 A1
(43) Pub. Date: Jun. 25, 2015

(54) MICROWAVE SWITCH AND METHOD OF MANUFACTURING MICROWAVE SWITCH

(71) Applicant: Electronics and Telecommunications Research Institute, Daejeon (KR)

(72) Inventors: Dong Hwan SHIN, Daejeon (KR); Seong Mo MOON, Daejeon (KR); In Bok YOM, Daejeon (KR)

(73) Assignee: Electronics and Telecommunications Research Institute, Daejeon (KR)

(21) Appl. No.: 14/502,257

(22) Filed: Sep. 30, 2014

(30) Foreign Application Priority Data
Dec. 19, 2013 (KR) 10-2013-0158965

(51) Int. Cl. H01P 1/15; H01L 25/07

(52) U.S. Cl. CPC H03H 7/383; H01L 25/071

(57) ABSTRACT

Provided is a microwave switch including at least one semiconductor device connected to a transmission line and grounded in parallel, and at least one inductor connected in series to the transmission line. When the semiconductor device is shorted, the inductor may perform impedance matching through an interaction with the semiconductor device.

### CROSS-REFERENCE TO RELATED APPLICATION

This application claims the benefit of Korean Patent Application No. 10-2013-0158965, filed on Dec. 19, 2013, in the Korean Intellectual Property Office, the disclosure of which is incorporated herein by reference.

### BACKGROUND

1. Field of the Invention

The present invention relates to a switch to be used in a microwave frequency band, and more particularly, to a low-loss and high-isolation microwave switch that may allow a signal to pass or block a signal using a semiconductor device on a transmission path along which a microwave frequency band signal is transmitted.

2.Description of the Related Art

In related arts, a microwave switch may be implemented using a series field-effect transistor (FET) switch in which an FET is connected in series to a transmission line along which a signal passes, as illustrated in FIG. 1, or may be implemented using a parallel FET switch in which an FET is connected to a transmission line along which a signal passes, and grounded in parallel, as illustrated in FIG. 2.

Major performance parameters of a microwave switch may include an insertion loss and an isolation performance. The insertion loss of the microwave switch refers to a loss of a signal passing through the microwave switch when the microwave switch is shorted (ON). The insertion loss may increase as a usable frequency increases. The isolation performance of the microwave switch refers to a degree at which signals are disallowed to pass when the microwave switch is disconnected (OFF). The isolation performance of the microwave switch may correspond to a value against an intensity of a signal passing through the microwave switch when the microwave switch is shorted (ON). The isolation performance may deteriorate as a usable frequency increases.

FIG. 3 is a circuit diagram illustrating an equivalent circuit when a microwave switch is shorted according to a related art.

Referring to FIG. 3, when an FET as an existing microwave switch is shorted, an ON resistor may be connected in series to a parasitic inductor.

The FET may include an undesired parasitic component, for example, the parasitic inductor. Due to such a parasitic component, an isolation performance of the microwave to switch may deteriorate.

The microwave switch may increase the isolation performance using a plurality of FETs connected to a transmission line and grounded in parallel, as illustrated in FIG. 4. However, the increase in the isolation performance may be restricted.

### SUMMARY

An aspect of the present invention provides a microwave switch that may restrict an insertion loss and increase an isolation performance in a wide band by allowing a signal to pass or blocking a signal using a semiconductor device on a transmission line along which a high-frequency band signal is transmitted, and by performing impedance matching in view of a parasitic component of the semiconductor device.

According to an aspect of the present invention, there is provided a microwave switch including at least one semiconductor device connected to a transmission line, and grounded in parallel, and at least one inductor connected in series to the transmission line. When the semiconductor device is shorted, the inductor may perform impedance matching through an interaction with the semiconductor device.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIGS. 1 and 2 are circuit diagrams illustrating microwave switches according to related arts;

FIG. 3 is a circuit diagram illustrating an equivalent circuit when a microwave switch is shorted according to a related art;

FIG. 4 is a circuit diagram illustrating a microwave switch according to another related art;

FIG. 5 is a circuit diagram illustrating a configuration of a microwave switch according to an embodiment of the present invention;

FIG. 6 is a circuit diagram illustrating an equivalent circuit when a microwave switch is shorted according to an embodiment of the present invention;

FIG. 7 is a circuit diagram illustrating a configuration of a microwave switch according to another embodiment of the present invention;

FIG. 8 is a circuit diagram illustrating a configuration of a microwave switch according to still another embodiment of the present invention;

FIG. 9 is a diagram illustrating an S11 simulation result of a microwave switch according to an embodiment of the present invention;

FIG. 10 is a diagram illustrating an S21 simulation result of a microwave switch according to an embodiment of the present invention;

FIG. 11 is a diagram illustrating isolation characteristics of a microwave switch according to an embodiment of the present invention; and

FIG. 12 is a flowchart illustrating a method of manufacturing a microwave switch according to an embodiment of the present invention.

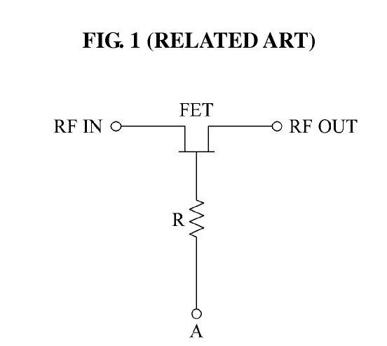

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

Hereinafter, a microwave switch according to an embodiment of the present invention will be described in detail with reference to the accompanying drawings. The microwave switch may refer to a component installed on a path along which a signal passes, for example, in a microwave frequency band communication system, to separate a transmitted/received signal or connect/disconnect the signal path.

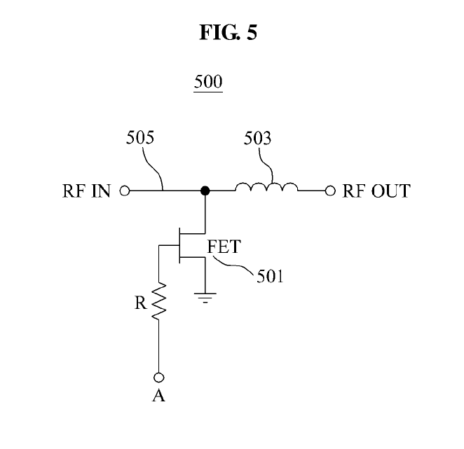

FIG. 5 is a circuit diagram illustrating a configuration of a microwave switch 500 according to an embodiment of the present invention.

Referring to FIG. 5, the microwave switch 500 may include a semiconductor device 501 and an inductor 503.

The semiconductor device 501 may be connected to a transmission path along which a radio frequency (RF) signal is transferred, and grounded in parallel. The transmission path may include, for example, a transmission line 505. When the semiconductor device 501 is shorted, the semiconductor device 501 may ground an RF signal input into the transmission line 505 to restrict an output of the RF signal on the transmission line 505, whereby the microwave switch 505 may perform an OFF operation.

The semiconductor device 501 may correspond to a switching device, for example, a field-effect transistor (FET).

The inductor 503 may be connected in series to the transmission line 505, and disposed on an output side of the semiconductor device 501. However, the disposition of the inductor 503 is not limited thereto. The inductor 503 may be disposed on an input side of the semiconductor device 501. In this example, the inductor 503 may perform impedance matching through an interaction with the semiconductor device 501 when the semiconductor device 501 is shorted.

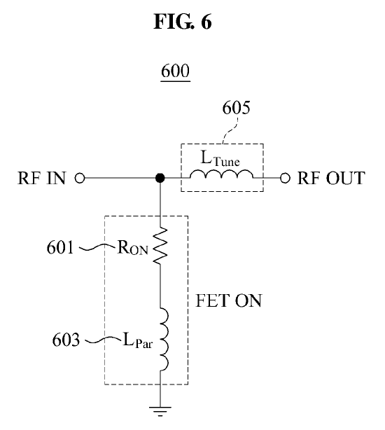

When the semiconductor device 501 is shorted, the microwave switch 500 may perform the OFF operation to reflect the RF signal input into the transmission line 505. In this example, when the inductor 503 performs impedance matching with the semiconductor device 501, the microwave switch 500 may compensate for deterioration in reflection characteristics caused by a parasitic inductance of the semiconductor device 501 to increase an isolation performance. As illustrated in FIG. 6, in an equivalent circuit of the microwave switch 500 in which the semiconductor device 501 is shorted, an ON resistor 601 and a parasitic inductor 603 may be connected in parallel to a transmission line, and an inductor 605 may be connected in series to the transmission line.

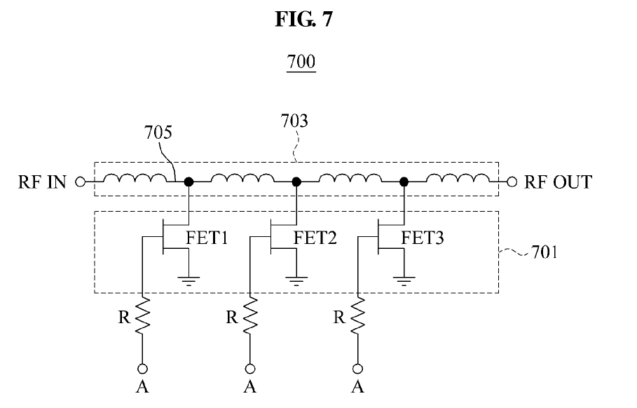

FIG. 7 is a circuit diagram illustrating a configuration of a microwave switch 700 according to another embodiment of the present invention.

Referring to FIG. 7, the microwave switch 700 may include a plurality of semiconductor devices 701 and a plurality of inductors 703.

The plurality of semiconductor devices 701 may be connected to a transmission line 705, grounded in parallel, and aligned above or below the transmission line 705.

The plurality of inductors 703 may be connected in series to the transmission line 705, and disposed between the plurality of semiconductor devices 701. The plurality of inductors 703 and the plurality of semiconductor devices 701 may be disposed alternately.

When the plurality of semiconductor devices 701 is shorted, the plurality of inductors 703 may perform impedance matching through an interoperation with the semiconductor devices 701.

In another example, the microwave switch 700 may perform impedance matching while forming a multistage switch using the plurality of semiconductor devices 701 and the plurality of inductors 703, thereby increasing an isolation performance.

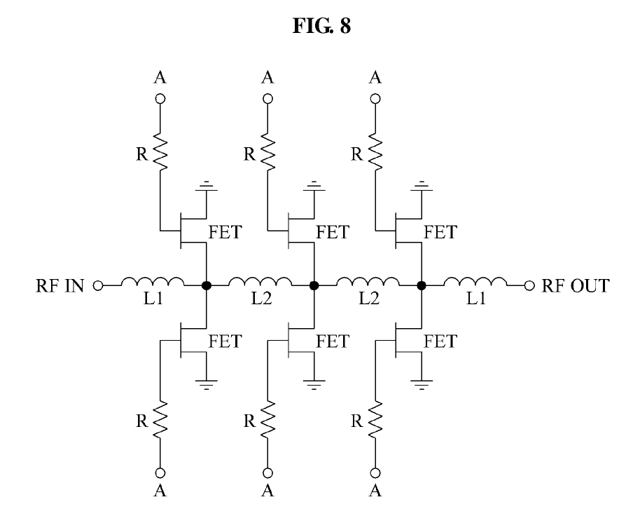

A microwave switch according to still another embodiment of the present invention may include a plurality of semiconductor devices aligned in pairs to face each other above and below a transmission line, as illustrated in FIG. 8.

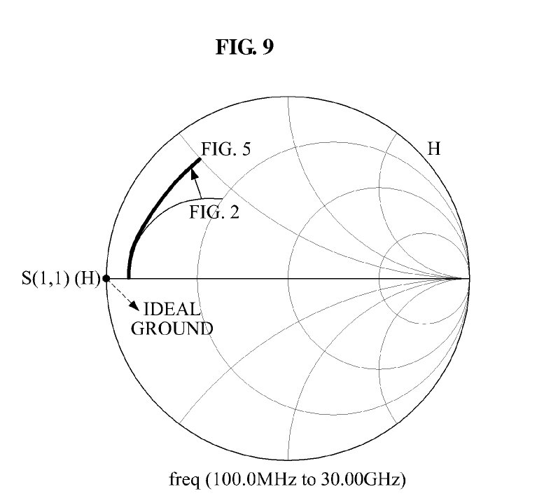

FIG. 9 is a diagram illustrating an S11 simulation result of a microwave switch according to an embodiment of the present invention.

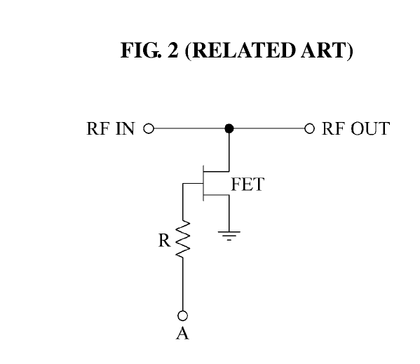

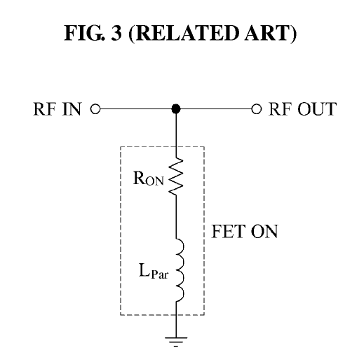

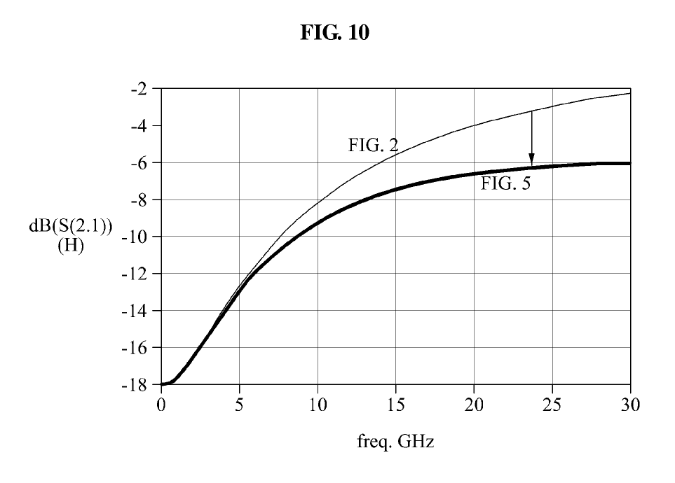

Referring to FIG. 9, the microwave switch, for example, the microwave switch 500 of FIG. 5, may not operate through an ideal ground due to parasitic components R_{ON} and L_{Par} of an FET. In particular, due to the parasitic inductance Lₚₐᵣ, the S11 simulation result may draw an inward curve on a Smith chart as a frequency increases, and reflection characteristics of a circuit may deteriorate. In contrast to an existing microwave switch with a decreased isolation performance, for example, the microwave switch of FIG. 2, the microwave switch, to for example, the microwave switch 500 of FIG. 5, may include a series inductor L_{Tune} to compensate for the deterioration in the reflection characteristics caused by the parasitic component of the FET, whereby the S11 simulation result may be smoothed toward an outer line of the Smith chart as the frequency increases. Thus, the deterioration in the reflection characteristics may be restricted, and the isolation performance may increase. In addition, as illustrated in FIG. 10, the microwave switch, for example, the microwave switch 500 of FIG. 5, may have a lower S21 simulation result than the existing microwave switch, for example, the microwave switch of FIG. 2, as the frequency increases, whereby the isolation performance may increase.

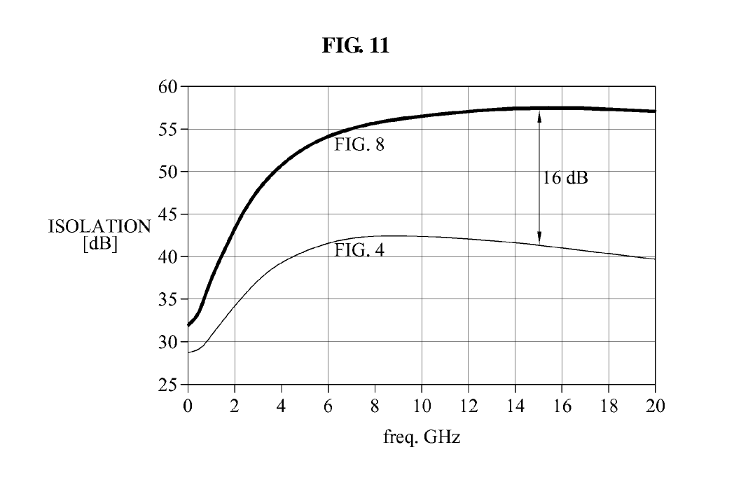

FIG. 11 is a diagram illustrating isolation characteristics of a microwave switch according to an embodiment of the present invention.

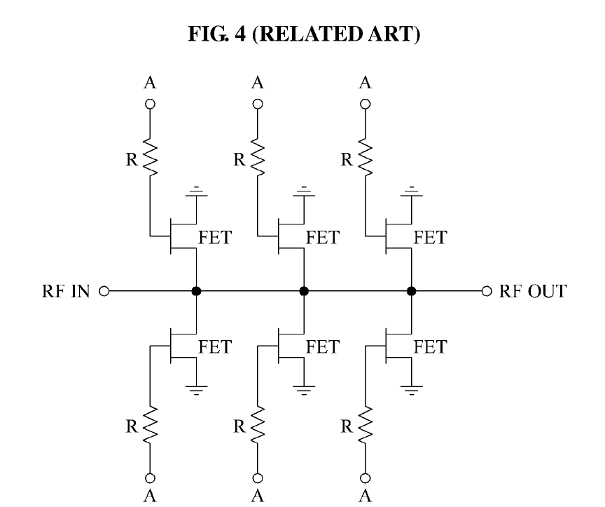

Referring to FIG. 11, the microwave switch, for example, the microwave switch of FIG. 8, may form a multistage switch using a plurality of semiconductor devices and a plurality of inductors, thereby achieving wide-band, low-loss, and high-isolation characteristics. The microwave switch, for example, the microwave switch of FIG. 8, may have an increased isolation performance throughout the band as a whole, and an increased isolation performance of about 16 decibels (dB) in a 15-gigahertz (GHz) band, when compared to an existing microwave switch, for example, the microwave switch of FIG. 4.

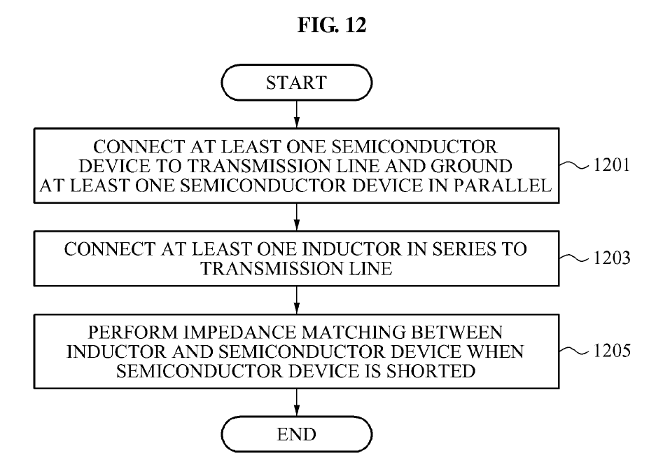

FIG. 12 is a flowchart illustrating a method of manufacturing a microwave switch according to an embodiment of the present invention.

Referring to FIG. 12, in operation 1201, at least one semiconductor device may be connected to a transmission line, and grounded in parallel. The semiconductor device may correspond to an FET.

When a plurality of semiconductor devices is to be connected to the transmission line, the plurality of semiconductor devices may be aligned above or below the transmission line.

In another example, the plurality of semiconductor devices may be aligned in pairs to face each other above and below the transmission line.

In operation 1203, at least one inductor may be connected in series to the transmission line.

When a plurality of semiconductor devices and a plurality of inductors are provided, the semiconductor devices and the inductors may be disposed alternately.

In operation 1205, impedance matching may be performed between the inductor and the semiconductor device when the semiconductor device is shorted. When the semiconductor device is shorted, the semiconductor device may ground a signal input into the transmission line to restrict an output of the input signal on the transmission line, whereby the microwave switch may perform an OFF operation.

According to exemplary embodiments of the present invention, it is possible to provide a microwave switch that may restrict an insertion loss and increase an isolation performance in a wide band by allowing a signal to pass or blocking a signal using a semiconductor device on a transmission line along which a high-frequency band signal is transmitted, and by performing impedance matching in view of a parasitic component of the semiconductor device.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A microwave switch comprising:
at least one semiconductor device connected to a transmission line, and grounded in parallel; and
at least one inductor connected in series to the transmission line,
wherein, when the semiconductor device is shorted,
the inductor performs impedance matching through an interaction with the semiconductor device.

2. The microwave switch of claim 1, wherein the semiconductor device grounds a signal input into the transmission line to restrict an output of the input signal, in response to the short.

3. The microwave switch of claim 1, wherein the semiconductor device corresponds to a field effect transistor (FET).

4. The microwave switch of claim 1, wherein, when a plurality of semiconductor devices and a plurality of inductors are provided, the semiconductor devices and the inductors are disposed alternately.

5. The microwave switch of claim 4, wherein the plurality of semiconductor devices is aligned above or below the transmission line.

6. The microwave switch of claim 4, wherein the plurality of semiconductor devices is aligned in pairs to face each other above and below the transmission line.

7. A method of manufacturing a microwave switch, the method comprising:
connecting at least one semiconductor device to a transmission line and grounding the at least one semiconductor device in parallel;
connecting at least one inductor in series to the transmission line; and
performing impedance matching between the inductor and the semiconductor device when the semiconductor device is shorted.

8. The method of claim 7, further comprising:
grounding, by the semiconductor device, a signal input into the transmission line to restrict an output of the input signal on the transmission line, in response to the short.

9. The method of claim 7, wherein the semiconductor device corresponds to a field effect transistor (FET).

10. The method of claim 7, wherein, when a plurality of semiconductor devices and a plurality of inductors are provided, the semiconductor devices and the inductors are disposed alternately.

11. The method of claim 10, wherein the connecting of the semiconductor device comprises aligning the plurality of semiconductor devices above or below the transmission line.

12. The method of claim 10, wherein the connecting of the semiconductor device comprises aligning the plurality of semiconductor devices in pairs to face each other above and below the transmission line.
